(19) United States
(12) Patent Application Publication
(10) Pub. No.: US 2008/0054953 A1
(43) Pub. Date: Mar. 6, 2008

(54) RSDS/LVDS Driving Circuits Suitable for Low Working Voltages

(76) Inventors: Cheng-Wei Chen, Taipei County (TW); Po-Ju Lee, Taipei County (TW); Chien-Cheng Tu, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/746,629

(22) Filed: May 9, 2007

(30) Foreign Application Priority Data
Aug. 29, 2006 (TW) 095131769

(51) Int. Cl. H03K 3/023

(52) U.S. Cl. 327/108

(57) ABSTRACT

A driving circuit includes a first switchable current module for providing a first current, a second switchable current module for providing a second current, a first switchable current source having an input end coupled to a first output end of the second switchable current module, a second switchable current source having an input end coupled to a second output end of the second switchable current module, a third switchable current source having an input coupled to a first output end of the first switchable current module, a fourth switchable current source having an input end coupled to a second output end of the first switchable current module, and a termination impedance circuit. The termination impedance circuit has a first end coupled to the first switchable current source and the third switchable current source, and a second end coupled to the second switchable current source and the fourth switchable current source.

### BACKGROUND OF THE INVENTION

1. Field of the Invention

The present invention relates to a RSDS/LVDS driving circuit, and more particularly, to a RSDS/LVDS driving circuit suitable for low working voltages.

2. Description of the Prior Art

Data transmission of computer peripheral facilities and applications of miscellaneous IC products are completed by an interface circuit capable of transmitting and receiving large data amounts due to processor speeds becoming higher and data amounts processed within a unit time becoming larger. The usage of current mode differential signal transmitters which compare differences between voltages or currents of input signals to output its current increases day by day in all kinds of transmitters. Whereof low voltage differential signaling (LVDS) transmitters, mini low voltage differential signaling (mini-LVDS) transmitters, and reduced swing differential signaling (RSDS) transmitters are one of the current mode differential signal transmitters. In general, these circuits are applied to image data transmission in industry nowadays.

Reduced swing differential signaling (RSDS) is a low-voltage technology used in data transmission systems. The use of low-voltage differential signaling for data transmission has grown rapidly due to the low power dissipation, high signal-to-noise ratio, low EMI emission, and high transmission speed characteristics inherent in such a system. Today's differential signaling systems usually have a swing, or peak-to-peak amplitude of 600 mv or less, depending on the particular derivation in use.

Low voltage differential signaling (LVDS) is a usual technology used in data transmission systems, which have a peak-to-peak amplitude between 250 mv to 450 mv. Low voltage differential signaling has characteristics of low power consumption at high transmission speed where its transmission speed can reach to more than 100 Mbps or even to 2 Gbps. Moreover, low voltage differential signaling has become the most popular different signal transmission interface due to the anti-noise ability, high signal-to-noise ratio, suitable for low power supply, robust transmission ability, and easy for integration characteristics.

Please refer to FIG. 1. FIG. 1 is a diagram of a RSDS/LVDS driving circuit 10 in the prior art. The RSDS/LVDS driving circuit 10 includes six transistors Q1, Q2, Q3, Q4, Q5 and Q6, and two resistors R1 and R2. Whereof the transistors Q1-Q4 are used as switch elements for providing different current paths, and the transistors Q5 and Q6 are used as a power supply of the RSDS/LVDS driving circuit 10 for providing positive current and negative current. The RSDS/LVDS driving circuit 10 receives a first input signal Vᵢₙ₁ and a second input signal Vᵢₙ₂ to output a first output signal Vₒᵤₜ₁ and a second output signal Vₒᵤₜ₂. The first input signal Vᵢₙ₁ and the second input signal Vᵢₙ₂ are differential input signals, and the first output signal Vₒᵤₜ₁ and the second output signal Vₒᵤₜ₂ are differential output signals. The transistors Q1 and Q2 are p-type metal oxide semiconductor transistors (PMOS), and the transistors Q3 and Q4 are n-type metal oxide semiconductor transistors (NMOS). The transistors Q2 and Q4 form a complementary metal oxide semiconductor pair. A gate terminal 122 of the transistor Q2 and a gate terminal 142 of the transistor Q4 are used for receiving the second input signal Vᵢₙ₂, and a drain terminal 124 of the transistor Q2 is coupled to a drain terminal 144 of the transistor Q4 (a node B) for outputting the first output signal Vₒᵤₜ₁. Similarly, the transistors Q1 and Q3 form another complementary metal oxide semiconductor pairs. A gate terminal 112 of the transistor Q1 and a gate terminal 132 of the transistor Q3 are used for receiving the first input signal Vᵢₙ₁, and a drain terminal 114 of the transistor Q1 is coupled to a drain terminal 134 of the transistor Q3 (a node A) for outputting the second output signal Vₒᵤₜ₂. The resistors R1 and R2 are coupled between the node A and the node B for matching an equivalent output impedance formed due to transmission line effect. Furthermore, the transistor Q5 is controlled by a bias voltage V_{BIAS}, and the transistor Q6 is controlled by a common mode feedback voltage for deciding a current value of a current I_{D} providing to the resistor R1 and R2. A source terminal 156 of the transistor Q5 is coupled to a second supply voltage V_{DD}, and a source terminal 166 of the transistor Q6 is coupled to a first supply voltage V_{SS} (that is the grounding point).

Please keep referring to FIG. 1. Operation modes of the RSDS/LVDS driving circuit 10 are described in the following. The transistors Q2 and Q3 are turned on and the transistors Q1 and Q4 are turned off when the first input signal Vᵢₙ₁ is high level and the second input signal Vᵢₙ₂ is low level. Hence, the current I_{D} supplied by the transistor Q5 flows through the transistor Q2 and draws out from the node B, and then the current I_{D} flows through the resistors R2 and R1 and the node A and back to the transistor Q3. Finally, the current I_{D} flows through the transistor Q6 and back to the first supply voltage V_{SS} (the grounding point). For that reason, a voltage of the node B is greater than a voltage of the node A, and the first output signal Vₒᵤₜ₁ of a high level and the second output signal Vₒᵤₜ₂ of a low level is built equivalently. Oppositely, the transistors Q1 and Q4 are turned on and the transistors Q2 and Q3 are turned off when the first input signal Vᵢₙ₁ is low level and the second input signal Vᵢₙ₂ is high level. Hence, the current ID supplied by the transistor Q5 flows through the transistor Q1 and draws out from the node A, and then the current ID flows through the resistors R1 and R2 and the node B and back to the transistor Q4. Finally, the current I_{D} flows through the transistor Q6 and back to the first supply voltage V_{SS} (the grounding point). For that reason, the voltage of the node A is greater than the voltage of the node B, and the first output signal Vₒᵤₜ₁ of the low level and the second output signal Vₒᵤₜ₂ of the high level is built equivalently. Thus it can be seen, voltage differences between the first output signal Vₒᵤₜ₁ and the second output signal Vₒᵤₜ₂ depend on resistances of the transistors R1 and R2 and the current value of the current I_{D}. An output signal of the RSDS/LVDS driving circuit 10 is the first output signal Vₒᵤₜ₁ minus the second output signal Vₒᵤₜ₂ and is equal to the current flows through the resistors R1 and R2 multiplied by the resistances of the resistors R1 and R2 when the first input signal Vᵢₙ₁ is high level and the second input signal Vᵢₙ₂ is low level, that is expressed as Vₒᵤₜ₁−Vₒᵤₜ₂=I_{D}×(R1+R2). At this time, the output signal corresponds to a logic “1” of the differential output signal. The output signal of the RSDS/LVDS driving circuit 10 is the first output signal Vₒᵤₜ₁ minus the second output signal Vₒᵤₜ₂ and is equal to the current flows through the resistors R1 and R2 multiplied by the resistances of the resistors R1 and R2 when the first input signal Vᵢₙ₁ is low level and the second input signal Vᵢₙ₂ is high level, that is expressed as Vₒᵤₜ₁−Vₒᵤₜ₂=(−I_{D})×(R1+R2). At this time, the output signal corresponds to the logic “0” of the differential output signal.

Please refer to FIG. 2, which is a diagram of another RSDS/LVDS driving circuit 20 in the prior art. The RSDS/LVDS driving circuit 20 includes a switchable current module 22, a first switchable current source 23, a second switchable current source 24, two transistors Q3 and Q4, a termination impedance circuit 28, and a current source 29. The transistors Q3 and Q4 are used as switch elements for providing different current paths, and the current source 29 is used for providing the current I_{D}. The RSDS/LVDS driving circuit 20 receives the first input signal Vᵢₙ₁ and the second input signal Vᵢₙ₂ to output the first output signal Vₒᵤₜ₁ and the second output signal Vₒᵤₜ₂. The first input signal Vᵢₙ₁ and the second input signal Vᵢₙ₂ are differential input signals, and the first output signal Vₒᵤₜ₁ and the second output signal Vₒᵤₜ₂ are corresponding differential output signals. In the embodiment, the transistors Q3 and Q4 are n-type metal oxide semiconductor transistors (NMOS). The gate terminal 142 of the transistor Q4 is used for receiving the second input signal Vᵢₙ₂, and an output end 246 of the second switchable current source 24 is coupled to the drain terminal 144 of the transistor Q4 (the node B) for outputting the first output signal Vₒᵤₜ₁. The gate 132 of the transistor Q3 is used for receiving the first input signal Vᵢₙ₁ and an output end 236 of the first switchable current source 23 is coupled to the drain terminal 134 of the transistor Q3 (the node A) for outputting the second output signal Vₒᵤₜ₂. The termination impedance circuit 28 is coupled between the node A and the node B for matching the equivalent output impedance formed due to transmission line effect. The switchable current module 22 includes a first input end 222 for receiving the first input signal Vᵢₙ₁, a second input end 224 for receiving the second input signal Vᵢₙ₂, a first output end 228 coupled to a first input end 232 of the first switchable current source 23, and a second output end 226 coupled to a first input end 242 of the second switchable current source 24. The first switchable current source 23 includes a second input end 234 coupled to the second supply voltage V_{DD}, and the second switchable current source 24 includes a second input end 244 coupled to the second supply voltage V_{DD}. An input end 292 of the current source 29 is coupled to the source terminal 136 of the transistor Q3 and to the source terminal 146 of the transistor Q4, and an output end 294 of the current source 29 is coupled to the first supply voltage V_{SS}.

Please keep referring to FIG. 2. Operation modes of the RSDS/LVDS driving circuit 20 are described in the following. The switchable current module 22 can provide different paths to the first switchable current source 23 and the second switchable current source 24. The second switchable current source 24 and the transistor Q3 are turned on and the first switchable current source 23 and the transistor Q4 are turned off when the first input signal Vᵢₙ₁ is high level and the second input signal Vᵢₙ₂ is low level. Hence, the current I_{D} flows through the second switchable current source 24 and draws out from the node B, and then the current I_{D} flows through the termination impedance circuit 28 and the node A and back to the transistor Q3. Finally, the current I_{D} flows through the current source 29 and back to the first supply voltage V_{SS} (the grounding point) to form a loop. For that reason, the voltage of the node B is greater than the voltage of the node A, and the first output signal Vₒᵤₜ₁ of the high level and the second output signal Vₒᵤₜ₂ of the low level is built equivalently. Oppositely, the first switchable current source 23 and the transistor Q4 are turned on and the second switchable current source 24 and the transistor Q3 are turned off when the first input signal Vᵢₙ₁ is low level and the second input signal Vᵢₙ₂ is high level. Hence, the current I_{D} flows through the first switchable current source 23 and draws out from the node A, and then the current I_{D} flows through the termination impedance circuit 28 and the node B and back to the transistor Q4. Finally, the current I_{D} flows through the current source 29 and back to the first supply voltage V_{SS} (the grounding point) to form a loop. For that reason, the voltage of the node A is greater than the voltage of the node B, and the first output signal Vₒᵤₜ₁ of the low level and the second output signal Vₒᵤₜ₂ of the high level is built equivalently. Thus it can be seen, voltage differences between the first output signal Vₒᵤₜ₁ and the second output signal Vₒᵤₜ₂ depend on a resistance (assumes R) of the termination impedance circuit 28 and the current value of the current I_{D}. An output signal of the RSDS/LVDS driving circuit 20 is the first output signal Vₒᵤₜ₁ minus the second output signal Vₒᵤₜ₂ and is equal to the current flows through the termination impedance circuit 28 multiplied by the resistance R of the termination impedance circuit 28 when the first input signal Vᵢₙ₁ is high level and the second input signal Vᵢₙ₂ is low level, that is expressed as Vₒᵤₜ₁−Vₒᵤₜ₂=I_{D}×R. At this time, the output signal corresponds to a logic “1” of the differential output signal. The output signal of the RSDS/LVDS driving circuit 20 is the first output signal Vₒᵤₜ₁ minus the second output signal Vₒᵤₜ₂ and is equal to the current flows through the termination impedance circuit 28 multiplied by the resistance R of the termination impedance circuit 28 when the first input signal Vᵢₙ₁ is low level and the second input signal Vᵢₙ₂ is high level, that is expressed as Vₒᵤₜ₁−Vₒᵤₜ₂=(−ID)×R. At this time, the output signal corresponds to the logic “0” of the differential output signal.

Please keep referring to FIG. 1 and FIG. 2. As shown in FIG. 1, the RSDS/LVDS driving circuit 10 includes four stages of transistors coupled in series totally, whereof the transistor Q5 is the first stage, the transistor Q1 and Q2 are the second stage, the transistor Q3 and Q4 are the third stage, and the transistor Q6 is the fourth stage. Although the RSDS/LVDS driving circuit 10 can work effectively under working voltages of 2.5V or 3.3V, is difficult to be designed for working under lower voltages (such as 1.8V) and is non-effective in usages of circuit area. As shown in FIG. 2, the RSDS/LVDS driving circuit 20 includes three stages of transistors coupled in series totally, whereof the first switchable current source 23 and the second switchable current source 24 are the first stage, the transistors Q3 and Q4 are the second stage, and the current source 29 is the third stage. Although the RSDS/LVDS driving circuit 20 can work effectively under lower working voltages and save quite a few area, but is restricted when applied to lower voltages.

Applications of LVDS driving circuits are already disclosed in U.S. Pat. No. 6,590,422 “Low Voltage Differential Signaling (LVDS) Drivers and Systems” and U.S. Pat. No. 6,927,608 “Low Power Low Voltage Differential Signaling Driver”. In U.S. Pat. No. 6,590,422 (as shown in FIG. 1), the operating method utilizes a traditional LVDS driving circuit that totally including four stages of transistors coupled in series to provide different current paths by turning on/off different transistors. In U.S. Pat. No. 6,927,608 (as shown in FIG. 2), the operating method utilizes one side switchable current framework to reduce one stage transistor, to make the LVDS driving circuit suitable for lower working voltages, and to save circuit area.

LVDS driving circuits are applied to all kinds of electronic products popularly due to having low power consumption characteristics under high-speed transmissions. In the prior art, although the RSDS/LVDS driving circuit 10 can work under the working voltage of 2.5V or 3.3V effectively, it is difficult to be designed for lower voltages (such as 1.8V). Although the RSDS/LVDS driving circuit 20 utilizes one side switchable current framework to make the RSDS/LVDS driving circuit 20 suitable for lower working voltages, it is restricted under still lower voltages.

### SUMMARY OF THE INVENTION

The claimed invention provides a driving circuit suitable for low working voltages. The driving circuit includes a first switchable current module, a second switchable current module, a first switchable current source, a second switchable current source, a third switchable current source, a fourth switchable current source, and a termination impedance circuit. The first switchable current module is used for providing a first current. The second switchable current module is used for providing a second current. The first switchable current source has an input end coupled to a first output end of the second switchable current module. The second switchable current source has an input end coupled to a second output end of the second switchable current module. The third switchable current source has an input end coupled to a first output end of the first switchable current module. The fourth switchable current source has an input end coupled to a second output end of the first switchable current module. The termination impedance circuit has a first end coupled to the first switchable current source and to the third switchable current source, and a second end coupled to the second switchable current source and to the fourth switchable current source. The driving circuit is a RSDS driving circuit, a LVDS driving circuit, or a mini-LVDS driving circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a RSDS/LVDS driving circuit in the prior art.

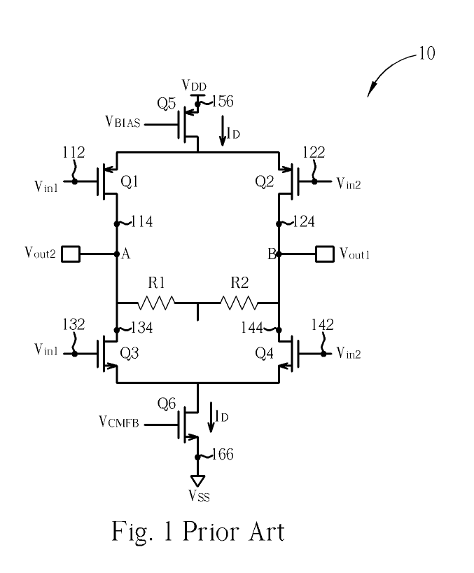

FIG. 2 is a diagram of another RSDS/LVDS driving circuit in the prior art.

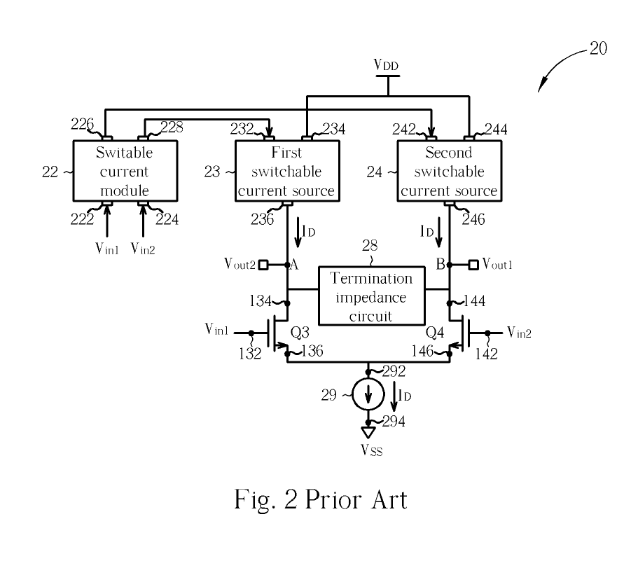

FIG. 3 is a diagram of a RSDS/LVDS driving circuit according to an embodiment of the present invention.

FIG. 4 is a diagram illustrating elements of the RSDS/LVDS driving circuit in FIG. 3.

FIG. 5 is a diagram of a RSDS/LVDS driving circuit according to another embodiment of the present invention.

FIG. 6 is a diagram illustrating elements of the RSDS/LVDS driving circuit in FIG. 5.

FIG. 7 is a diagram of an application system according to an embodiment of the present invention.

FIG. 8 is a diagram of an application system according to another embodiment of the present invention.

### DETAILED DESCRIPTION

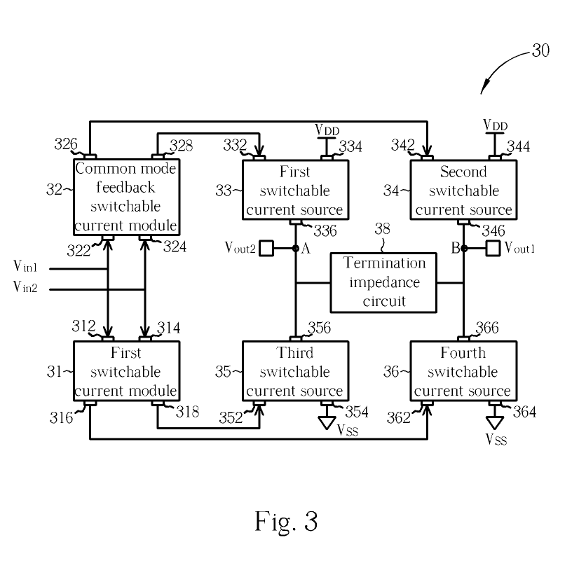

Please refer to FIG. 3. FIG. 3 is a diagram of a RSDS/LVDS driving circuit 30 according to an embodiment of the present invention. The RSDS/LVDS driving circuit 30 includes a first switchable current module 31, a common mode feedback switchable current module 32, a first switchable current source 33, a second switchable current source 34, a third switchable current source 35, a fourth switchable current source 36, and a termination impedance circuit 38. The RSDS/LVDS driving circuit 30 receives the first input signal Vᵢₙ₁ and the second input signal Vᵢₙ₂ to output the first output signal Vₒᵤₜ₁ and the second output signal Vₒᵤₜ₂. The first input signal Vᵢₙ₁ and the second input signal Vᵢₙ₂ are differential input signals, and the first output signal Vₒᵤₜ₁ and the second output signal Vₒᵤₜ₂ are corresponding differential output signals. The first switchable current module 31 has a first input end 312 for receiving the first input signal Vᵢₙ₁, a second input end 314 for receiving the second input signal Vᵢₙ₂, a first output end 316 coupled to a first input end 362 of the fourth switchable current source 36, and a second output end 318 coupled to a first input end 352 of the third switchable current source 35. The common mode feedback switchable current module 32 has a first input end 322 for receiving the first input signal Vᵢₙ₁, a second input end 324 for receiving the second input signal Vᵢₙ₂, a first output end 326 coupled to a first input end 342 of the second switchable current source 34, and a second output end 328 coupled to a first input end 332 of the first switchable current source 33. The first switchable current source 33 has a second input end 334 coupled to the second supply voltage V_{DD}, the second switchable current source 34 has a second input end 344 coupled to the second supply voltage V_{DD}, the third switchable current source 35 has a second input end 354 coupled to the first supply voltage V_{SS}, and the fourth switchable current source 36 has a second input end 364 coupled to the second supply voltage V_{SS}. An output end 336 of the first switchable current source 33 is coupled to an output end 356 of the third switchable current source 35 (the node A) for outputting the second output signal Vₒᵤₜ₂, an output end 346 of the second switchable current source 34 is coupled to an output end 366 of the fourth switchable current source 36 (the node B) for outputting the first output signal Vₒᵤₜ₁. The termination impedance circuit 38 is coupled between the node A and the node B for matching the equivalent output impedance formed due to transmission line effect.

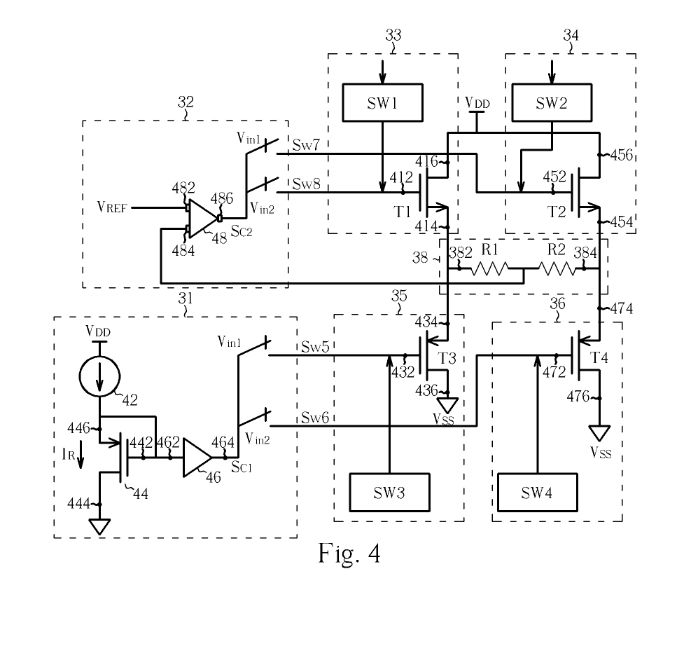

Please refer to FIG. 4. FIG. 4 is a diagram illustrating elements of the RSDS/LVDS driving circuit 30 in FIG. 3. The first switchable current module 31 includes a current source 42, a current mirror 44, a buffer 46, a fifth switch SW5, and a sixth switch SW6. The current source 42 is used for providing a reference current I_{R}. The current mirror 44 is a transistor which has a control end 442 coupled to the current source 42 and to an input end 462 of the buffer 46, a first end 446 coupled to the current source 42, and a second end 444 coupled to the first supply voltage V_{SS}. The input end 462 of the buffer 46 is coupled to the current source 42 and the current mirror 44, and an output end 464 of the buffer 46 is used for outputting a first bias voltage SC1. The fifth switch SW5 has a first end coupled to the output end 464 of the buffer 46, a second end coupled to the third switchable current source 35, and a control end for receiving the first input signal Vᵢₙ₁. The fifth switch SW5 is controlled by the first input signal Vᵢₙ₁ to be turned on/off. The sixth switch SW6 has a first end coupled to the output end 464 of the buffer 46, a second end coupled to the fourth switchable current source 36, and a control end for receiving the second input signal Vᵢₙ₂. The sixth switch SW6 is controlled by the second input signal Vᵢₙ₂ to be turned on/off. The first input signal Vᵢₙ₁ is used for controlling the fifth switch SW5, and the fifth switch SW5 is turned on to make a value of an input node 432 of the third switchable current source 35 equal the first bias voltage SC1 when the first input signal Vᵢₙ₁ is high level. The second input signal Vᵢₙ₂ is used for controlling the sixth switch SW6, and the sixth switch SW6 is turned on to make a value of an input node 472 of the fourth switchable current source 36 equal the first bias voltage SC1 when the second input signal Vᵢₙ₂ is high level. The common mode feedback switchable current module 32 includes an amplifier 48, a seventh switch SW7, and an eighth switch SW8. The amplifier 48 has a first input end 482 for receiving a reference voltage V_{REF}, a second input end 484 coupled to the termination impedance circuit 38, and an output end 486 for outputting a second bias voltage Sc2. The seventh switch SW7 has a first end coupled to an output end 486 of the amplifier 48, a second end coupled to the second switchable current source 34, and a control end for receiving the first input signal Vᵢₙ₁. The seventh switch SW7 is controlled by the first input signal Vᵢₙ₁ to be turned on/off. The eighth switch SW8 has a first end coupled to the output end 486 of the amplifier 48, a second end coupled to the first switchable current source 33, and a control end for receiving the second input signal Vᵢₙ₂. The eighth switch SW8 is controlled by the second input signal Vᵢₙ₂ to be turned on/off. The common mode feedback switchable current module 32 further includes a reference voltage generator (not shown in FIG. 4) coupled to the first input end 482 of the amplifier 48 for generating the reference voltage V_{REF}. The first input signal Vᵢₙ₁ is used for controlling the seventh switch SW7. The seventh switch SW7 is turned on to make a value of an input node 452 of the second switchable current source 34 equal the second bias voltage SC2 when the first input signal Vᵢₙ₁ is high level. The second input signal Vᵢₙ₂ is used for controlling the eighth switch SW8. The eighth switch SW8 is turned on to make a value of an input node 412 of the first switchable current source 33 equal the second bias voltage SC2 when the second input signal Vᵢₙ₂ is high level.

Please keep referring to FIG. 4. The first switchable current source 33 includes a first transistor T1 and a first switch SW1. The first transistor T1 has a control end 412 coupled to the first switch SW1 and to the eighth switch SW8, a first end 416 coupled to the second supply voltage V_{DD}, a second end 414 coupled to the first end 382 of the termination impedance circuit 38. The second switchable current source 34 includes a second transistor T2 and a second switch SW2. The second transistor T2 has a control end 452 coupled to the second switch SW2 and to the seventh switch SW7, a first end 456 coupled to the second supply voltage V_{DD}, a second end 454 coupled to the second end 384 of the termination impedance circuit 38. The third switchable current source 35 includes a third transistor T3 and a third switch SW3. The third transistor T3 has a control end 432 coupled to the third switch SW3 and to the fifth switch SW5, a first end 436 coupled to the first supply voltage V_{SS}, a second end 434 coupled to the first end 382 of the termination impedance circuit 38. The fourth switchable current source 36 includes a fourth transistor T4 and a fourth switch SW4. The fourth transistor T4 has a control end 472 coupled to the fourth switch SW4 and to the sixth switch SW6, a first end 476 coupled to the first supply voltage V_{SS}, a second end 474 coupled to the second end 384 of the termination impedance circuit 38. The termination impedance circuit 38 includes the resistors R1 and R2 whereof a node between the resistor R1 and R2 provides a common mode feedback to the common mode feedback switchable current module 32.

Please refer to FIG. 3 and FIG. 4. Operation modes of the RSDS/LVDS driving circuit 30 are described in the following. The first switchable current module 31 can provide the reference current I_{R} to its output end, and different current paths are switched to the third switchable current source 35 or the fourth switchable current source 36 through the fifth switch SW5 and the sixth switch SW6. The common mode feedback switchable current module 32 is used for comparing the common mode feedback, and the seventh switch SW7 and the eighth switch SW8 are turned on/off for different current paths according to changes of the first input signal Vᵢₙ₁ and the second input signal Vᵢₙ₂. The fifth switch SW5 is turned on and the sixth switch SW6 is turned off when the first input signal Vᵢₙ₁ is high level and the second input signal Vᵢₙ₂ is low level. The third transistor T3 is turned on by a voltage V_{GS} of the reference current I_{R}, at this time the fourth transistor T4 is turned off due to the fourth switch SW4 being pulled to ground. With regard to the positive current path, the seventh switch SW7 is turned on and the eighth switch SW8 is turned off, and the second transistor T2 is turned on due to the second switch SW2 not being pulled to ground and the first transistor T1 is turned off due to the first switch SW1 being pulled to ground. The positive current flows from the second transistor T2 into the resistors R2 and R1, and then signals feedback to the amplifier 48 to form a feedback loop. Hence, the whole system starts from the second supply voltage V_{DD} and current flows from the second transistor T2 into the resistors R2 and R1, and then flows through the third transistor T3 to ground to form a loop. The voltage of the node B is greater than the voltage of the node A, and the first output signal Vₒᵤₜ₁ of a high level and the second output signal Vₒᵤₜ₂ of a low level is built equivalently (a positive differential voltage amplitude). Oppositely, the fifth switch SW5 is turned off and the sixth switch SW6 is turned on when the first input signal Vᵢₙ₁ is low level and the second input signal Vᵢₙ₂ is high level. The fourth transistor T4 is turned on by the voltage V_{GS} of the reference current I_{R}, at this time the third transistor T3 is turned off due to the third switch SW3 being pulled to ground. With regard to the positive current path, the seventh switch SW7 is turned off and the eighth switch SW8 is turned on, and the first transistor T1 is turned on due to the first switch SW1 not being pulled to the second supply voltage V_{DD} and the fourth transistor T4 is turned off due to the fourth switch SW2 being pulled to the second supply voltage V_{DD}. The positive current flows from the first transistor T1 into the resistors R1 and R2, and then signals feedback to the amplifier 48 to form a feedback loop. Hence, the whole system starts from the second supply voltage V_{DD} and currents flows from the first transistor T1 into the resistors R1 and R2, and then flows through the fourth transistor T4 to ground to form a loop. The voltage of the node A is greater than the voltage of the node B, and the first output signal Vₒᵤₜ₁ of the low level and the second output signal Vₒᵤₜ₂ of the high level is built equivalently (a negative differential voltage amplitude).

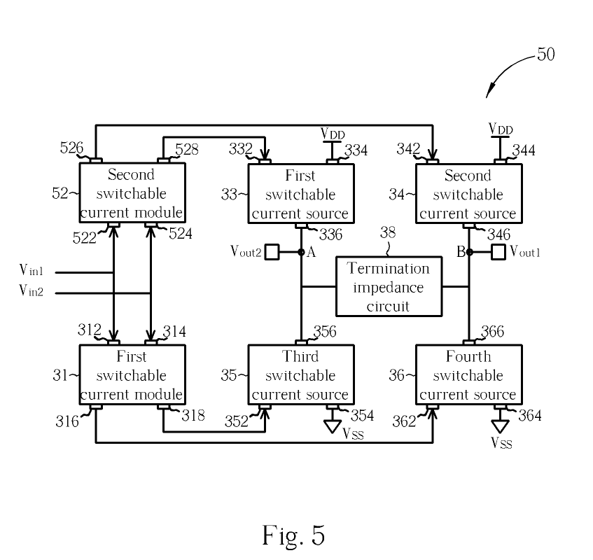

Please refer to FIG. 5, which is a diagram of a RSDS/LVDS driving circuit 50 according to another embodiment of the present invention. The RSDS/LVDS driving circuit 50 includes the first switchable current module 31, a second switchable current module 52, the first switchable current source 33, the second switchable current source 34, the third switchable current source 35, the fourth switchable current source 36, and the termination impedance circuit 38. The RSDS/LVDS driving circuit 50 is similar to the RSDS/LVDS driving circuit 30 in FIG. 3. Differences between FIG. 5 and FIG. 3 are that the second switchable current module 52 is used for replacing the common mode feedback switchable current module 32. The second switchable current module 52 has a first input end 522 for receiving the first input signal Vᵢₙ₁, a second input end 524 for receiving the second input signal Vᵢₙ₂, a first output end 526 coupled to the first input end 342 of the second switchable current source 34, and a second output end 528 coupled to the first input end 332 of the first switchable current source 33. Connecting manners of other elements, such as the first switchable current module 31, the first switchable current source 33, the second switchable current source 34, the third switchable current source 35, the fourth switchable current source 36, and the termination impedance circuit 38, are the same as connecting manners described in FIG. 3.

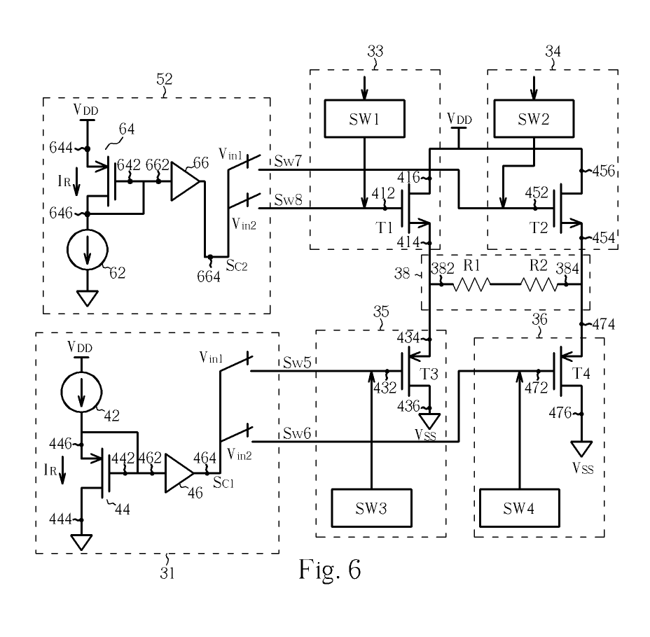

Please refer to FIG. 6. FIG. 6 is a diagram illustrating elements of the RSDS/LVDS driving circuit 50 in FIG. 5. Elements in FIG. 6 are similar to elements in FIG. 4. Differences between FIG. 6 and FIG. 4 are that the second switchable current module 52 is used for replacing the common mode feedback switchable current module 32. The second switchable current module 52 includes a current source 62, a current mirror 64, a buffer 66, a seventh switch SW7, and an eighth switch SW8. The current source 62 is used for providing the reference current I_{R}. The current mirror 64 is a transistor having a control end 642 coupled to the current source 62 and to an input end 662 of the buffer 66, a first end 646 coupled to the current source 62, and a second end 644 coupled to the second supply voltage V_{DD}. The input end 662 of the buffer 66 is coupled to the current source 62 and the current mirror 64, and an output end 664 of the buffer 66 is used for outputting a second bias voltage SC2. The seventh switch SW7 has a first end coupled to the output end 664 of the buffer 66, a second end coupled to the second switchable current source 34, and a control end for receiving the first input signal Vᵢₙ₁. The seventh switch SW7 is controlled by the first input signal Vᵢₙ₁ to be turned on/off. The eighth switch SW8 has a first end coupled to the output end 664 of the buffer 66, a second end coupled to the first switchable current source 33, and a control end for receiving the second input signal Vᵢₙ₂. The eighth switch SW8 is controlled by the second input signal Vᵢₙ₂ to be turned on/off. The first input signal Vᵢₙ₁ is used for controlling the seventh switch SW7. The seventh switch SW7 is turned on to make the value of the input node 452 of the second switchable current source 34 equal the second bias voltage SC2 when the first input signal Vᵢₙ₁ is high level, wherein the second switchable current source 34 to be turned on/off is controlled by the first input signal Vᵢₙ₁. The second input signal Vᵢₙ₂ is used for controlling the eighth switch SW8. The eighth switch SW8 is turned on to make the value of the input node 412 of the first switchable current source 33 equal the second bias voltage SC2 when the first second signal Vᵢₙ₂ is high level, wherein the first switchable current source 33 to be turned on/off is controlled by the second input signal Vᵢₙ₂. Connecting manners of other elements are similar to connecting manners in FIG. 4.

Please refer to FIG. 5 and FIG. 6. Operation modes of the RSDS/LVDS driving circuit 50 are described in the following. The first switchable current module 31 can provide the reference current I_{R} to its output end, and different current paths are switched to the third switchable current source 35 or the fourth switchable current source 36 through the fifth switch SW5 and the sixth switch SW6. The second switchable current module 52 can provide the reference current I_{R} to its output end, and different current paths are switched through the seventh switch SW7 and the eighth switch SW8. The fifth switch SW5 is turned on and the sixth switch SW6 is turned off when the first input signal Vᵢₙ₁ is high level and the second input signal Vᵢₙ₂ is low level. The third transistor T3 is turned on by the voltage V_{GS} of the reference current I_{R}, at this time the fourth transistor T4 is turned off due to the fourth switch SW4 being pulled to ground. With regard to the positive current path, the seventh switch SW7 is turned on and the eighth switch SW8 is turned off when the first input signal Vᵢₙ₁ is high level and the second input signal Vᵢₙ₂ is low level. The second transistor T2 is turned on by the voltage V_{GS} of the reference current I_{R}, at this time the first transistor T1 is turned off due to the first switch SW1 being pulled to the second supply voltage V_{DD}. The whole system starts from the second supply voltage V_{DD} and the current flows from the second transistor T2 into the resistors R2 and R1, and then flows through the third transistor T3 to ground to form a loop. The voltage of the node B is greater than the voltage of the node A, and the first output signal Vₒᵤₜ₁ of a high level and the second output signal Vₒᵤₜ₂ of a low level is built equivalently (the positive differential voltage amplitude). Oppositely, the fifth switch SW5 is turned off and the sixth switch SW6 is turned on when the first input signal Vᵢₙ₁ is low level and the second input signal Vᵢₙ₂ is high level. The fourth transistor T4 is turned on by the voltage V_{GS} of the reference current I_{R}, at this time the third transistor T3 is turned off due to the third switch SW3 being pulled to ground. With regard to the positive current path, the seventh switch SW7 is turned off and the eighth switch SW8 is turned on when the first input signal Vᵢₙ₁ is low level and the second input signal Vᵢₙ₂ is high level. The first transistor T1 is turned on by the voltage V_{GS} of the reference current I_{R}. At this time, the second transistor T2 is turned off due to the second switch SW2 being pulled to the second supply voltage V_{DD}. Hence, the whole system starts from the second supply voltage V_{DD} and the current flows from the first transistor T1 into the resistors R1 and R2, and then flows through the fourth transistor T4 to ground to form a loop. The voltage of the node A is greater than the voltage of the node B, and the first output signal Vₒᵤₜ₁ of the low level and the second output signal Vₒᵤₜ₂ of the high level is built equivalently (a negative differential voltage amplitude).

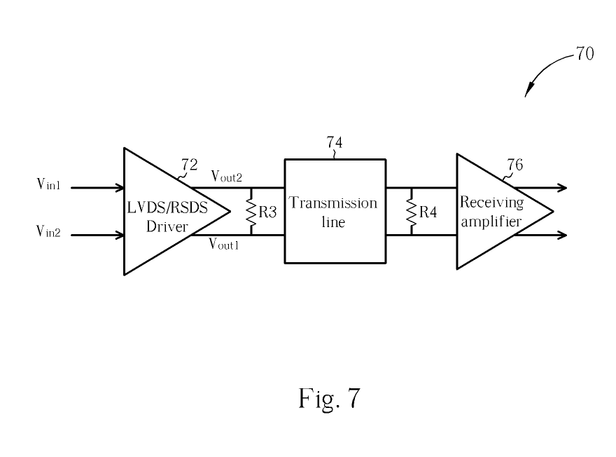

Please refer to FIG. 7, which is a diagram of an application system 70 according to an embodiment of the present invention. The application system 70 includes a LVDS/RSDS driver 72, a loading resistor R3, a transmission line 74, an input resistor R4, and a receiving amplifier 76. The LVDS/RSDS driver 72 is the LVDS/RSDS driving circuit 30 or the LVDS/RSDS driving circuit 50 mentioned in FIG. 3 and FIG. 5 for receiving the first input signal Vᵢₙ₁ and the second input signal Vᵢₙ₂ to output the first output signal Vₒᵤₜ₁ and the second output signal Vₒᵤₜ₂. The loading resistor R3 is coupled between two output ends of the LVDS/RSDS driver 72, and the input resistor R4 is coupled between two input ends of the receiving amplifier 76. The first output signal Vₒᵤₜ₁ and the second output signal Vₒᵤₜ₂ are transmitted by the transmission line 74 and then are received by the receiving amplifier 76. Whereof the first output signal Vₒᵤₜ₁ and the second output signal Vₒᵤₜ₂ are single pair LVDS/RSDS differential signals, and the application system 70 is a point-to-point structure.

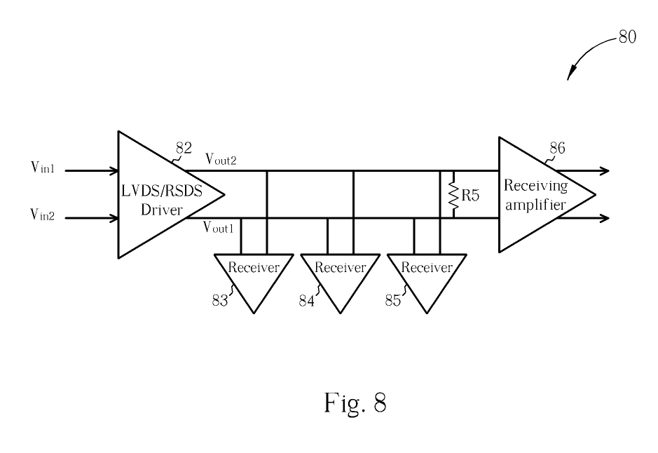

Please refer to FIG. 8. FIG. 8 is a diagram of an application system 80 according to another embodiment of the present invention. The application system 80 includes a LVDS/RSDS driver 82, a plurality of receivers 83-86, and an input resistor R5. The LVDS/RSDS driver 82 is the LVDS/RSDS driving circuit 30 or the LVDS/RSDS driving circuit 50 mentioned in FIG. 3 and FIG. 5 for receiving the first input signal Vᵢₙ₁ and the second input signal Vᵢₙ₂ to output the first output signal Vₒᵤₜ₁ and the second output signal Vₒᵤₜ₂. The input resistor R5 is coupled between two input ends of the receiving amplifier 86. The application system 80 is a multi-drop structure.

The abovementioned embodiments are presented merely for describing the present invention, and in no way should be considered to be limitations of the scope of the present invention. The common mode feedback switchable current module 32 can be implemented by a current module the same as the first switchable current module 31, such as the second switchable current module 52. Connecting manners of the feedback switchable current module 32 and the first switchable current module 31 can be inverted and are not limited to the embodiments in the present invention. Each transistor mentioned above can be a metal oxide semiconductor transistor (MOS) or a bipolar junction transistor (BJT). The driving circuits of the present invention are applied to not only LVDS driving circuits but also mini-LVDS driving circuits and RSDS driving circuits. Furthermore, the LVDS/RSDS driving circuits can be applied to both the point-to-point structure and the multi-drop structure.

From the above descriptions, the present invention provides a RSDS/LVDS driving circuit suitable for low working voltages. The driving circuits can work under even lower working voltages such as 1.5V-1.8V due to switchable current structures being applied to two supply voltage sides (V_{DD} and V_{SS}). The present invention can further reduce one stage of transistors in series to save chipset area effectively. Furthermore, output stages are not controlled by input signals directly that can lower switching noise and electromagnetic interference (EMI). Circuits of control switches need not to drive large output transistors directly, which can lessen sizes of digital circuit logic for reducing EMI.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A driving circuit suitable for low working voltages comprising:
a first switchable current module used for providing a first current;
a second switchable current module used for providing a second current;
a first switchable current source having an input end coupled to a first output end of the second switchable current module;
a second switchable current source having an input end coupled to a second output end of the second switchable current module;
a third switchable current source having an input end coupled to a first output end of the first switchable current module;
a fourth switchable current source having an input end coupled to a second output end of the first switchable current module; and
a termination impedance circuit having a first end coupled to the first switchable current source and to the third switchable current source, and a second end coupled to the second switchable current source and to the fourth switchable current source.

2. The driving circuit of claim 1, wherein the first switchable current source comprises:
a first transistor having an input end coupled to a first power supply and an output end coupled to the first end of the termination impedance circuit; and
a first switch coupled to a control end of the first transistor, the first switch used for controlling turning on and turning off the first transistor.

3. The driving circuit of claim 2, wherein the second switchable current source comprises:
a second transistor having an input end coupled to the first power supply and an output end coupled to the second end of the termination impedance circuit; and
a second switch coupled to a control end of the second transistor, the second switch used for controlling turning on and turning off the second transistor.

4. The driving circuit of claim 3, wherein the third switchable current source comprises:
a third transistor having an input end coupled to a second power supply and an output end coupled to the first end of the termination impedance circuit; and
a third switch coupled to a control end of the third transistor, the third switch used for controlling turning on and turning off the third transistor.

5. The driving circuit of claim 4, wherein the fourth switchable current source comprises:
a fourth transistor having an input end coupled to the second power supply and an output end coupled to the second end of the termination impedance circuit; and
a fourth switch coupled to a control end of the fourth transistor, the fourth switch used for controlling turning on and turning off the fourth transistor.

6. The driving circuit of claim 5, wherein the first transistor, the second transistor, the third transistor, and the fourth transistor are each a metal oxide semiconductor transistor (MOS).

7. The driving circuit of claim 5, wherein the first transistor, the second transistor, the third transistor, and the fourth transistor are each a bipolar junction transistor (BJT).

8. The driving circuit of claim 1, wherein the first switchable current module comprises:
a current source used for providing a reference current;
a current mirror coupled to the current source; and
a buffer having an input end coupled to the current source and to the current mirror, and an output end used for outputting a first bias voltage.

9. The driving circuit of claim 8, wherein the current mirror is a transistor, the transistor having a control end coupled to the current source and to the input end of the buffer, a first end coupled to the current source, and a second end coupled to the first power supply.

10. The driving circuit of claim 8, wherein the first switchable current module further comprises:
a fifth switch having a first end coupled to the output end of the buffer, a second end coupled to the control end of the first transistor, and a control end used for receiving a first input signal, the first input signal used for controlling turning on and turning off the fifth switch and further used for controlling turning on and turning off the first switch; and
a sixth switch having a first end coupled to the output end of the buffer, a second end coupled to the control end of the second transistor, and a control end used for receiving a second input signal, the second input signal used for controlling turning on and turning off the sixth switch and further used for controlling turning on and turning off the second switch.

11. The driving circuit of claim 1, wherein the second switchable current module comprises:
a current source used for providing a reference current;
a current mirror coupled to the current source; and
a buffer having an input end coupled to the current source and to the current mirror, and an output end used for outputting a second bias voltage.

12. The driving circuit of claim 11, wherein the current mirror is a transistor, the transistor having a control end coupled to the current source and to the input end of the buffer, a first end coupled to the current source, and a second end coupled to the first power supply.

13. The driving circuit of claim 12, wherein the second switchable current module further comprises:
a seventh switch having a first end coupled to the output end of the buffer, a second end coupled to the control end of the fourth transistor, and a control end used for receiving the first input signal, the first input signal used for controlling turning on and turning off the seventh switch and further used for controlling turning on and turning off the fourth switch; and
an eighth switch having a first end coupled to the output end of the buffer, a second end coupled to the control end of the third transistor, and a control end used for receiving the second input signal, the second input signal used for controlling turning on and turning off the eighth switch and further used for controlling turning on and turning off the third switch.

14. The driving circuit of claim 13 further comprising:
a first input voltage terminal coupled between the control end of the fifth switch and the control end of the seventh switch for generating the first input signal; and
a second input voltage terminal coupled between the control end of the sixth switch and the control end of the eighth switch for generating the second input signal.

15. The driving circuit of claim 1, wherein the second switchable current module comprises:
an amplifier having a first input end for receiving a reference voltage, a second input end coupled to the termination impedance circuit, and an output end used for outputting the second bias voltage.

16. The driving circuit of claim 15 wherein the second switchable current module further comprises:
a seventh switch having a first end coupled to the output end of the amplifier, a second end coupled to the control end of the fourth transistor, and a control end used for receiving the first input signal, the first input signal used for controlling turning on and turning off the seventh switch and further used for controlling turning on and turning off the fourth switch; and
an eighth switch having a first end coupled to the output end of the amplifier, a second end coupled to the control end of the third transistor, and a control end used for receiving the second input signal, the second input signal used for controlling turning on and turning off the eighth switch and further used for controlling turning on and turning off the third switch.

17. The driving circuit of claim 16 further comprising:
a first input voltage terminal coupled between the control end of the fifth switch and the control end of the seventh switch for generating the first input signal; and
a second input voltage terminal coupled between the control end of the sixth switch and the control end of the eighth switch for generating the second input signal.

18. The driving circuit of claim 16, wherein the second switchable current module further comprises a reference voltage generator coupled to the first input end of the amplifier for generating the reference voltage.

19. The driving circuit of claim 1, wherein the driving circuit is a RSDS (reduced swing differential signal) driving circuit.

20. The driving circuit of claim 1, wherein the driving circuit is a LVDS (low voltage differential signal) driving circuit or a mini-LVDS (mini low voltage differential signal) driving circuit.
